(19) United States
(12) Patent Application Publication
(10) Pub. No.: US 2020/0319819 A1
(43) Pub. Date: Oct. 8, 2020

(54) Method and Apparatus for Improving Parity Redundant Array of Independent Drives Write Latency in NVMe Devices

(71) Applicant: DELL PRODUCTS, LP, Round Rock, TX (US)

(72) Inventors: Chandrashekar Nelogal, Round Rock, TX (US); Kevin T. Marks, Georgetown, TX (US); James P. Giannoules, Round Rock, TX (US)

(21) Appl. No.: 16/372,671

(22) Filed: Apr. 2, 2019

(51) Int. Cl. G06F 3/06; G06F 11/10; G11C 29/52

(52) U.S. Cl. CPC G06F 3/0659; G06F 3/0619; G11C 29/52; G06F 3/0689; G06F 11/1068; G06F 3/0688

(57) ABSTRACT

An information handling system includes a host to write a non-volatile memory express (NVMe) command, and a plurality of NVMe devices configured as a RAID array. Each of the NVMe devices is configured to use internal hardware resources to perform offload operations of the NVMe command.

### FIELD OF THE DISCLOSURE

This disclosure generally relates to information handling systems, and more particularly relates to improving parity redundant array of independent drives (RAID) write latency in non-volatile memory express (NVMe) devices.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

An information handling system includes a host to write a non-volatile memory express (NVMe) command, and a plurality of NVMe devices configured as a RAID array. Each of the NVMe devices may use internal hardware resources to perform offload operations of the NVMe command.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram of an information handling system configured to interface with non-volatile memory express (NVMe) devices, according to an embodiment of the present disclosure;

FIG. 2 is a sequence diagram of a method for implementing an NVMe command to improve parity RAID write latency in the information handling system, according to an embodiment of the present disclosure;

FIG. 3 is a block diagram of a portion of the information handling system performing a partial XOR offloading operation between a host and a data drive, according to an embodiment of the present disclosure;

FIG. 4 is a block diagram of a portion of the information handling system performing a partial XOR offloading operation between a host and a parity drive, according to an embodiment of the present disclosure;

FIG. 5 is a flow chart showing a method of improving parity RAID write latency in the information handling system, according to an embodiment of the present disclosure; and

FIG. 6 is a flow chart showing a method of implementing the first and second XOR offloading operations of the NVMe command in a read-modify-write process, according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings.

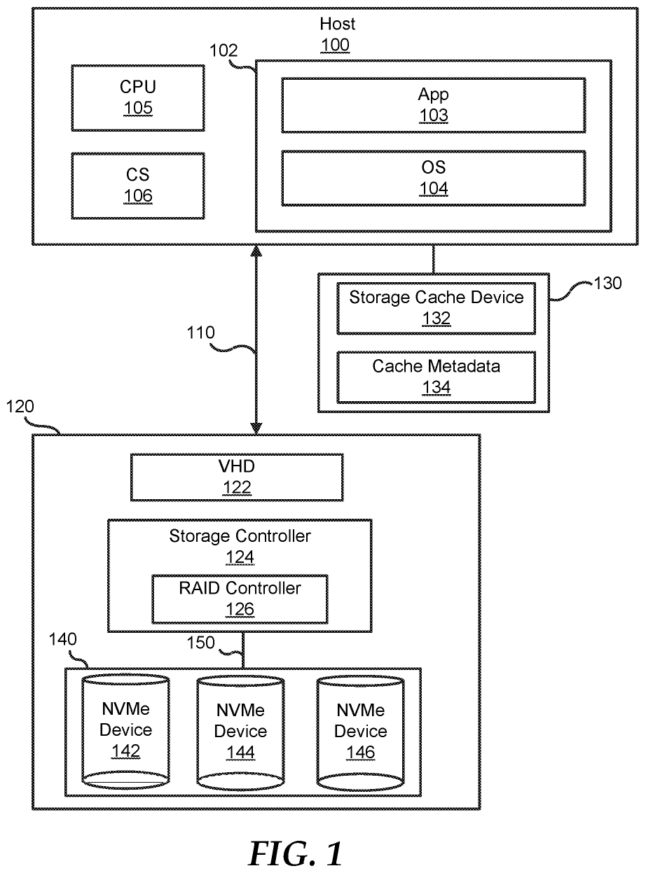

FIG. 1 illustrates an embodiment of a general information handling system configured as a host system 100. For purposes of this disclosure, the information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, the information handling system can be a personal computer, a laptop computer, a smart phone, a tablet device or other consumer electronic device, a network server, a network storage device, a switch router or other network communication device, or any other suitable device and may vary in size, shape, performance, functionality, and price. Furthermore, the information handling system can include processing resources for executing machine-executable code, such as a central processing unit (CPU), a programmable logic array (PLA), an embedded device such as a System-on-a-Chip (SoC), or other control logic hardware. Information handling system can also include one or more computer-readable medium for storing machine-executable code, such as software or data. Additional components of information handling system can include one or more storage devices that can store machine-executable code, one or more communications ports for communicating with external devices, and various input and output (I/O) devices, such as a keyboard, a mouse, and a video display. Information handling system can also include one or more buses operable to transmit information between the various hardware components.

In an embodiment, the host 100 includes a system memory 102 that further includes an application program 103 executing within an operating system (OS) 104. The host 100 includes one or more CPUs 105 that are coupled to the system memory 102 in which the application program 103 and the operating system 104 have been stored for execution by the CPU(s). A chip set 106 may further provide one or more input/output (I/O) interfaces to couple external devices to the host 100.

The host 100 may generate I/O transactions 110 targeting a coupled storage subsystem 120 that includes a virtual hard drive (VHD) 122. The host 100 further employs a storage cache device 130 that is configured to cache the I/O transactions 110. The storage cache device 130 is analogous to an L1 data cache employed by the CPU. The storage cache device 130 includes one or more cache storage devices 132 and cache metadata 134 that is maintained by a storage cache module in OS 104. The host 100 enables and supports the storage cache device 130 with the storage cache module in the OS 104.

At the storage subsystem 120, a storage controller 124 may map the VHD 122 to a RAID array 140. In an embodiment, the storage controller 124 includes a RAID controller 126 that may be configured to control multiple NVMe devices 142-146 that make up the RAID array 140. The number of NVMe devices presented is for ease of illustration and different numbers of NVMe devices may be utilized in the RAID array 140. The NVMe devices may be independent solid state data storage drives (SSD) that may be accessed through a peripheral component interconnect express (PCIe) bus 150.

In an embodiment, the host 100 is configured to write an NVMe command. The NVMe command may be directed to the storage controller 124 and the RAID array 140. In this embodiment, the NVMe command may include features to improve parity RAID write latency in the information handling system.

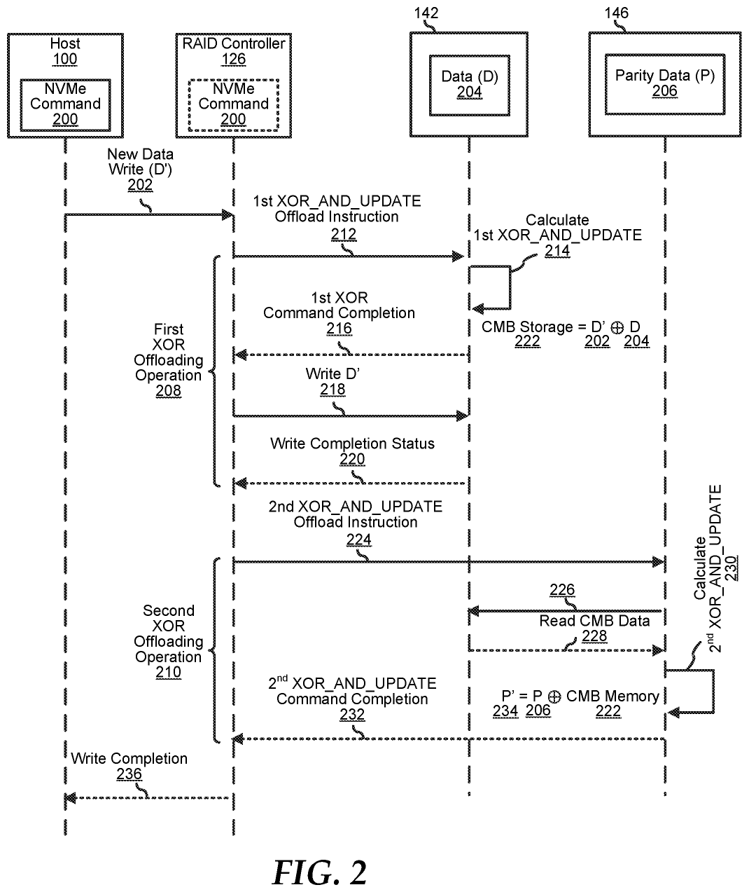

FIG. 2 shows a read-modify-write process of a RAID parity calculation for the RAID array. The RAID parity calculation may be performed, for example, in case new data is to be written on a data drive and parity data on a parity drive needs to be recalculated. In another example, the RAID parity calculation is performed when a command from the host calls for the parity data calculation in the parity drive. The data and parity drives include the NVMe devices that are configured to store data and parity, respectively. In these examples, performance of partial XOR offload operations such as an XOR calculation by each one of the NVMe devices may break the need for data movement between the RAID controller and the NVMe devices for data writes to parity based RAID volumes. As such, RAID controller's traditional role as an entity that transfers, manipulates, and updates data may be reduced into a mere orchestrating of data movement and facilitating data protection with use of the RAID methodologies. The partial XOR offload operations in the read-modify-write process may be extended to other methods of RAID parity calculation where each NVMe device is configured to receive the NVMe command and to perform the XOR offload operations using its internal hardware resources to ease the calculation burden of the RAID controller. The NVMe command, for example, includes instructions for the servicing NVMe device to perform the XOR calculations, and to update corresponding data drive or parity drive after completion of the XOR calculations. In this example, the NVMe device may utilize its peer to peer capabilities to directly access data from a peer NVMe device.

As an overview of the read-modify-write process, the host 100 sends a write command including a new data write (D′) that replaces a value of data (D) in the data drive. Based from this write command, the RAID controller sends a first XOR offload instruction that is implemented by the data drive. The data drive performs the first XOR offload instruction and stores results to a buffer memory. The data drive may further fetch the D′ to update the data drive. To update parity, the RAID controller is aware of stored result's location and it sends a second XOR offload instruction to the servicing parity drive. The parity drive performs the second XOR offload instruction between the results stored in the memory buffer and parity data to generate a new parity data (P′). The parity drive is then updated with the new parity value and the RAID controller may send a write completion to the host.

In an embodiment, an NVMe command 200 includes a request to write the new data, which is represented by a D′ 202. For example, the D′ 202 is used to overwrite the value of data (D) 204 in the NVMe device 142 of the RAID array 140. As a consequence, parity data (P) 206 in the NVMe device 146 needs to be recalculated and re-written to the same parity drive. In this embodiment, the D 204 and the P 206 may belong to the same RAID stripe. Furthermore, for this RAID stripe, the NVMe device 142 is configured to store data while the NVMe device 146 is configured to store the parity data. The NVMe devices 142 and 146 may be referred to as the data drive and parity drive, respectively.

To implement the new data write and the parity update in the NVMe devices 142 and 146, respectively, a first XOR offloading operation 208 and a second XOR offloading operation 210 are performed by the corresponding NVMe devices on the RAID array. The RAID array, for example, is configured as a RAID 5 that uses disk striping with parity. Other RAID configurations such as RAID 6 may utilize the XOR offloading and updating operations as described herein.

In an embodiment, the first XOR offloading operation 208 may involve participation of the RAID controller 126 and the NVMe device 142. The first XOR offloading operation includes sending of a first XOR offload instruction 212 by the RAID controller to the NVMe device 142, an XOR calculation 214 performed by the NVMe device 142, a sending of a first XOR command completion 216 by the NVMe device 142 to the RAID controller, a writing 218 of the D′ by the RAID controller to the NVMe device 142, and a sending of new data write completion status 220 by the NVMe device 142 to the RAID controller to complete the first XOR_AND_UPDATE offload instruction. In this embodiment, the first XOR command completion 216 may not be sent and the NVMe device 142 may fetch the D′ to replace the D 204. After overwriting of the D 204, the first XOR offload instruction 212 is completed and the NVMe device may send the write completion status 220. In this embodiment still, a result of the XOR calculation between the D and D′ is stored in controller memory buffer (CMB) storage 222.

The CMB storage may include a persistent memory or a volatile memory. That is, the XOR offloading operation is not dependent on persistency of intermediate data and the RAID controller may decide on the usage of the intermediate data and longevity of the data in the CMB storage. In an embodiment, the CMB storage may include PCIe bar address registers (BARs) or regions within the BAR that can be used to store either generic intermediate data or data associated with the NVMe block command. The BARs may be used to hold memory addresses used by the NVMe device. In this embodiment, each NVMe device in the RAID array may include a CMB storage that facilitates easy access of data during the offload operations to ease the calculation burden of the RAID controller, to minimize use of RAID controller DRAMs, and to open the RAID controller interfaces to other data movement or bus utilization.

In an embodiment, the second XOR offloading operation 210 may involve participation of the RAID controller, the NVMe device 146 as the parity drive, and the NVMe device 142 as the peer drive that stored previous partial XOR operation results in the temporary buffer such as the CMB storage 222. The second XOR offloading operation includes sending of a second XOR offload instruction 224 by the RAID controller 126 to the NVMe device 146, requesting a CMB memory range 226 by the NVMe device 146 to the peer NVMe device 142, a reading 228 by the NVMe device 146 of the stored results including the requested CMB memory range from the CMB storage, an XOR calculation 230 by the NVMe device 146, and a sending of a second XOR offloading command completion 232 by the NVMe device 146 to the RAID controller. In this embodiment, the XOR calculation is performed on the read CMB memory range stored in the CMB storage 222 and the parity data 206 to generate a new parity data (P′) 234. The P′ 234 is then stored into the NVMe device 146 to replace the P206. Afterward, the RAID controller may send a write completion 236 to the host 100 to complete the D′ 202.

In an embodiment, the first XOR offload instruction 212 and the second XOR offload instruction 224 may take the form:

XOR_AND_UPDATE(Input1,Input2,Output)

where the XOR_AND_UPDATE indicates the NVMe command or instruction for the servicing NVMe device to perform partial XOR offload operation and to perform the update after completion of the partial XOR calculation. The action to XOR command may be performed to update a logical block address (LBA) location such as when the D′ is written to the data drive or when the P′ is written to update the parity drive. The action to the XOR command may also result to holding the resultant buffer in the temporary memory buffer such as the CMB storage. In this embodiment, the two inputs Input1 and Input 2 of the XOR_AND_UPDATE command may be taken from at least two of the following: from LBA range (starting LBA and number of logical blocks) on the NVMe drive that is servicing the command; from an LBA range on a peer drive where the peer drive is identified with its BDF (Bus, Device, Function); or from a memory address range. The output parameter Output of the XOR_AND_UPDATE command may include the LBA range of the NVMe drive that is servicing the command, or the memory address range with the same possibilities as the input parameter. The memory address range may allow addressing of the CMB storage on the local drive, CMB storage on the remote drive, the host memory, and or remote memory.

For example, the first input for the first XOR offload instruction 212 includes the 204 on a first LBA range on the NVMe device 142 that is servicing the XOR_AND_UPDATE command while the second input includes the D′ that may be fetched from an input buffer of a host memory or a RAID controller's memory. In another example, the D′ may be fetched from the host memory or the RAID controller's memory and stored in the second LBA range of the same NVMe device. In this other example, the two inputs D and D′ are read from the first and second LBA ranges, respectively, of the same NVMe device. After the completion of partial XOR operation between the D and the D′, the D′ may be written to replace the D 204 on the first LBA range. Furthermore, the updating portion of the XOR_AND_UPDATE command includes storing of the partial XOR calculation results to a memory address range in the CMB storage. The memory address range in the CMB storage includes the output parameter in the XOR_AND_UPDATE command. In an embodiment, the RAID controller takes note of this output parameter and is aware of the memory address range in the CMB storage where the partial XOR calculation results are stored.

To update the parity drive, the two inputs for the second XOR offload instruction 224 may include, for example, the memory address range of the CMB storage where the previous partial XOR calculation results are stored, and the LBA range on the servicing NVMe device 146 that stored the parity data. The two inputs in this case do not use logical blocks but rather, one input includes the LBA range while the other input includes the memory address range of the CMB storage. In an embodiment, the NVMe device 146 is configured to access the stored partial XOR calculation results from the peer drive such as the NVMe device 142. In this embodiment, the NVMe device 146 may access the CMB storage without going through the RAID controller since the CMB storage is attached to the peer drive. For example, the NVMe device 146 is connected to the peer NVMe device 142 through a PCIe switch. In this example, the NVMe device 146 may access the stored partial XOR calculation results by using the memory address range of the CMB storage. The memory address range is one of the two inputs to the second XOR offload instruction.

In an embodiment, the XOR_AND_UPDATE command may be integrated to the NVMe protocol such that each NVMe device in the RAID array may be configured to receive the NVMe command and to use its internal hardware resources to perform the offload operations of the NVMe command.

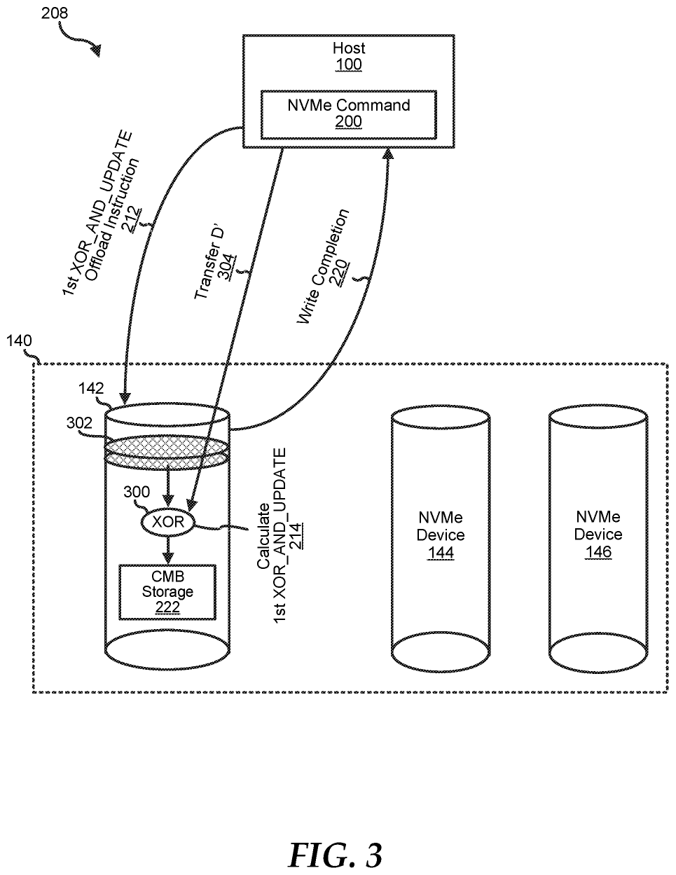

FIG. 3 is an example implementation of the first XOR offloading operation such as the first XOR offloading operation 208 during the read-modify-write process to update the data drive and to store partial XOR operation results in the CMB storage. The data drive, for example, includes the NVMe device 142 that is configured to service the first XOR offload instruction from the RAID controller. In this example, the NVMe device 142 may include internal hardware resources such as the CMB storage 222, an XOR circuit 300, and storage media 302. Each NVMe device in the RAID array may further include internal processors that facilitate the implementation of the XOR_AND_UPDATE command in the servicing drive.

In an embodiment and for the write operation that includes the writing of the D′ to the NVMe device 142, the host 100 may send the first XOR offload instruction 212 to the data drive. The host may refer to host memory or RAID controller's memory. In this embodiment, the two inputs to the first XOR offload instruction may include a first LBA range on the storage media 302, and the other input may be taken from an input buffer of the host memory or the RAID controller's memory. The host 100 may transfer 304 the D′ in response to data request from the NVMe device and the internal processors may perform the XOR calculations between the D and the D′. In a case where the host transfers 304 the D′ to a second LBA range on the storage media 302, then the other input for the first XOR offload instruction may include the second LBA range on the same NVMe device. In this regard, the internal processors of the data drive may read the current data on the first LBA range and the D′ on the second LBA range, and perform the XOR calculations between D and D′. After the XOR calculations, the D′ is written to the first LBA range to replace the D. Here, the write D′ is similar to write D′ 218 in FIG. 2.

The XOR circuit 300 may include a hardware circuit with an application program that performs the XOR operation between the two inputs of the XOR_AND_UPDATE command. In an embodiment, the first input includes the read current data on the first LBA range while the second input D′ may be received from the write from the host. In this embodiment, the XOR circuit performs the XOR operations to generate results that will be stored, for example, in a first memory address range of the CMB storage 222. The usage and or longevity of the stored data in the first memory address range of the CMB storage 222 may be managed by the RAID controller. In other embodiment, the generated results may be stored in the CMB storage on a remote drive, on the host memory, and or the remote memory. After completion of the first XOR offloading operation, the NVMe device may send the write completion status 220 to the RAID controller.

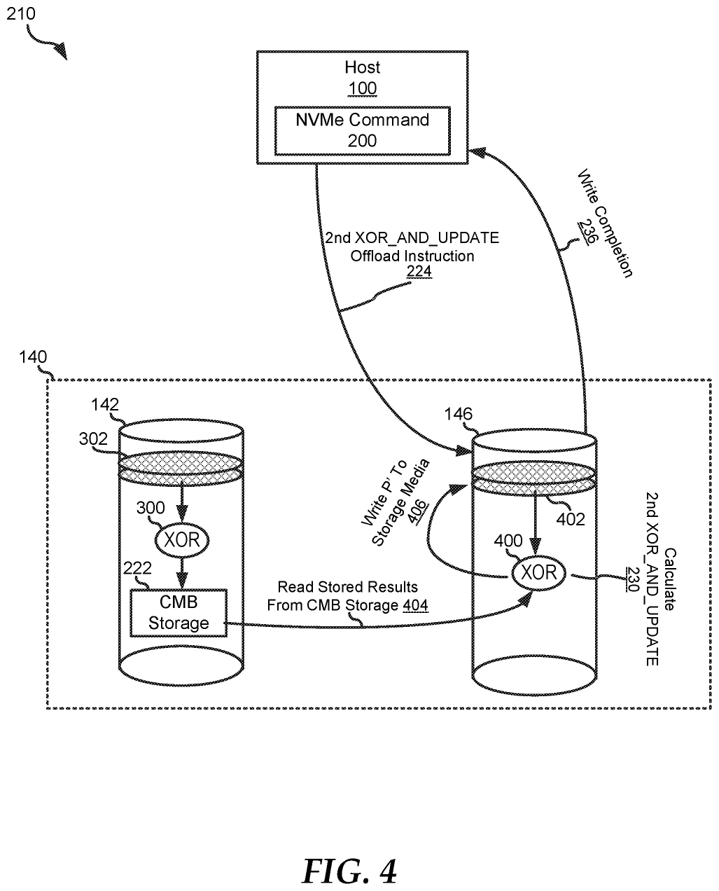

FIG. 4 is an example implementation of the second XOR offloading operation such as the second XOR offloading operation 210 during the read-modify-write process to update the parity drive. The parity drive, for example, includes the NVMe device 146 that is configured to service the second XOR offload instruction from the RAID controller. In this example, the NVMe device 146 may include its own internal hardware resources such as an XOR circuit 400 and storage media 402.

In an embodiment and to update the parity drive, the host 100 may send the second XOR offload instruction 212 to the NVMe device 146. The two inputs for the second XOR offload instruction may include, for example, a third LBA range on the storage media 402 and the first memory address range of CMB storage 222. In this example, the third LBA range may include the parity data such as the P 206 in FIG. 2. In this embodiment, the internal processors of the NVMe device may read the parity data on the third LBA range and also read stored results 404 from first memory address range of the CMB storage 222. Here, the read stored result 404 is similar to read CMB storage 226 in FIG. 2.

The XOR circuit 400 may include a hardware circuit that performs the XOR operation between the two inputs. In an embodiment, the XOR circuit performs the XOR operations to generate the P′ in a write buffer. In this embodiment still, the parity drive writes the P′ from the write buffer to the storage media 406 where the P′ may be stored in the same or different LBA range where the old parity data was originally stored. The parity drive may maintain atomicity of data for the XOR operation and updates the location only after successful XOR calculation or operation has been performed or completed. After completion of the second XOR offloading operation, the NVMe device that is servicing the command may send the write completion 236 to the host.

In another embodiment such as the read-peers method, the new parity data may be calculated by performing the XOR operation on the value of the D′ and data of the NVMe device 144 in the same RAID stripe. In this other embodiment, the read and XOR offload operations may be performed at each NVMe device following the XOR offloading operation and updating processes described herein. However, the P′ is written on a different peer drive such as the parity drive.

For both read-modify-write and read-peers processes, XOR offload operations may be performed in parallel by distributing the XOR_AND_UPDATE commands to multiple devices instead of centralized implementation at the RAID controller. This may result to optimized data path, reduces number of steps required for I/O completion, and leverages PCIe peer-to-peer transaction capabilities.

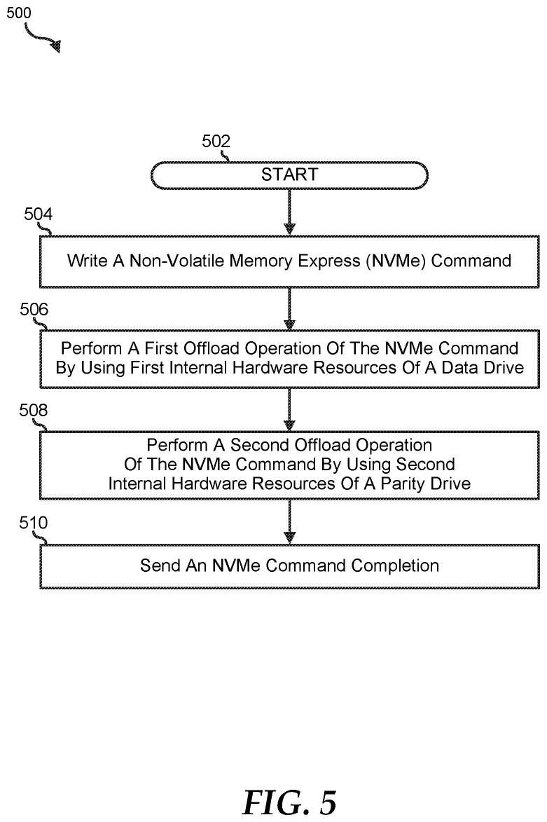

FIG. 5 shows a method 500 of improving parity RAID write latency on the information handling device, starting at block 502. At block 504, the host 100 writes the NVMe command 200. At block 506, the data drive uses its internal hardware resources to perform the first offload operation. At block 508, the parity drive uses its own internal hardware resources to perform the second offload operation. At block 510, the RAID controller sends NVMe command completion to the host.

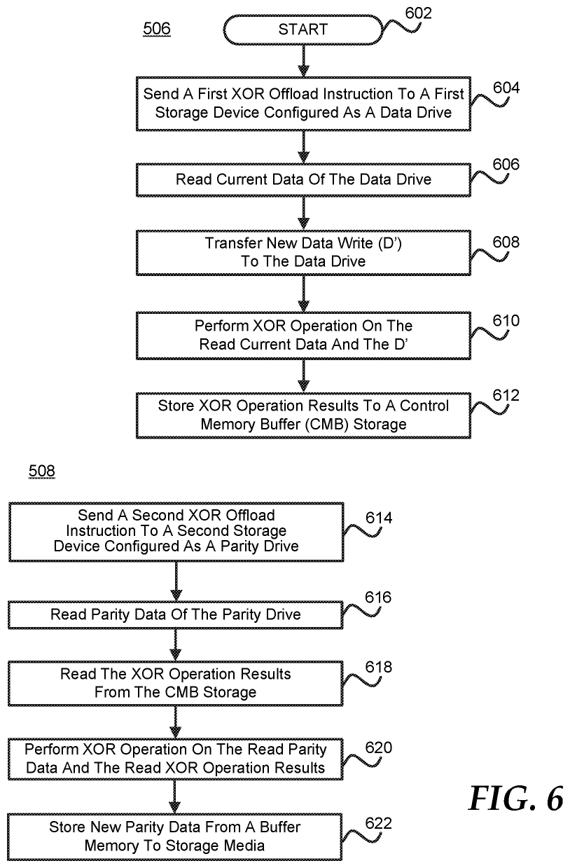

FIG. 6 shows the method of implementing the blocks 506 and 508 of FIG. 5 for improving parity RAID write latency on the information handling device, starting at block 602. At block 604, sending the first XOR offload instruction to the data drive. The first XOR offload instruction includes the XOR_AND_UPDATE command with two inputs and one output. At block 606, the data drive reads current data from a first input range such as a first LBA range. At block 608, the host transfers the D′ to a second input range such as a second LBA range of the data drive. At block 610, the data drive performs the XOR operation on the current data and the D′. At block 612, the data drive stores results of the XOR operation to a memory address range in the CMB storage.

At block 614, sending the second XOR offload instruction 224 to the parity drive. The second XOR offload instruction includes the XOR_AND_UPDATE command with two inputs and one output. At block 616, reading old parity data from the third LBA range in the parity drive. The third LBA range, for example, is one of the two inputs of the XOR_AND_UPDATE command. At block 618, reading the results from the memory address range of the CMB storage 226 by the parity drive. At block 620, performing the XOR calculation 230 by the NVMe device 146 to generate the P′. And at block 622, storing the P′ from the write buffer or buffer memory to the storage media.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents.

Devices, modules, resources, or programs that are in communication with one another need not be in continuous communication with each other, unless expressly specified otherwise. In addition, devices, modules, resources, or programs that are in communication with one another can communicate directly or indirectly through one or more intermediaries.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

1. An information handling system having improved parity redundant array of independent drives (RAID) write latency, comprising:
a host to write a non-volatile memory express (NVMe) command;
a RAID controller to receive the NVMe command from the host, and to provide offload instructions based on the NVMe command; and
a plurality of NVMe devices configured as a RAID array wherein each one of the NVMe devices is configured to use internal hardware resources to perform offload operations based on the offload instructions based on the NVMe command.

2. The information handling system of claim 1, wherein the offload operations include a first XOR offloading operation and a second XOR offloading operation.

3. The information handling system of claim 2, wherein the first XOR offloading operation including: sending of a first XOR offload instruction to the NVMe device configured as a data drive; reading current data of the data drive; transferring new data write (D′) to the data drive; performing XOR operation on the read current data and the D′; and storing a result of the XOR operation to a controller memory buffer (CMB) storage.

4. The information handling system of claim 3, wherein internal hardware resources of the data drive includes an XOR circuit and the CMB storage.

5. The information handling system of claim 3, wherein the CMB storage is included in the data drive.

6. The information handling system of claim 3, wherein the second XOR offloading operation includes two inputs and one output, wherein the two inputs are chosen from any two of: a logical block address (LBA) range on the NVMe device that is servicing the NVMe command, the LBA range on a peer NVMe device, or a memory address range.

7. The information handling system of claim 6, wherein the output includes either one of: the LBA range on the NVMe device that is servicing the NVMe command, or the memory address range.

8. The information handling system of claim 2, wherein the second XOR offloading operation including: sending of a second XOR offload instruction to the NVMe device configured as a parity drive; reading parity data of the parity drive; reading stored results from a controller memory (CMB) storage; and performing XOR operation on the read parity data and the read stored results from the CMB storage.

9. The information handling system of claim 8, wherein results of the performed XOR operation are stored on a memory address range on the parity drive.

10. A method of improving parity redundant array of independent drives (RAID) write latency, comprising:
writing, by a host, of a non-volatile memory express (NVMe) command;
receiving, by a RAID controller, the NVMe command from the host
providing, by the RAID controller, offload instructions based on the NVMe command; and
performing, by internal hardware resources of an NVMe device, offload operations based on the offload instructions based on the NVMe command.

11. The method of claim 10, wherein the offload operations include a first XOR offloading operation and a second XOR offloading operation.

12. The method of claim 11, wherein the first XOR offloading operation including: sending of a first XOR offload instruction to the NVMe device configured as a data drive; reading current data of the data drive; transferring new data write (D′) to the data drive; performing XOR operation on the read current data and the D′; and storing a result of the XOR operation to a controller memory buffer (CMB) storage.

13. The method of claim 12, wherein the data drive includes an XOR circuit and the CMB storage as the internal hardware resources.

14. The method of claim 12, wherein the CMB storage is attached to the data drive.

15. The method of claim 12, wherein the second XOR offloading operation includes two inputs and one output, wherein the two inputs are chosen from any two of: a logical block address (LBA) range on the NVMe device that is servicing the NVMe command, the LBA range on a peer NVMe device, or a memory address range.

16. The method of claim 12, wherein the output includes either one of: the LBA range on the NVMe device that is servicing the NVMe command, or the memory address range.

17. An information handling system, comprising:
a host to write a non-volatile memory express (NVMe) command;
a redundant array of independent drives (RAID) controller to receive the NVMe command from the host, and to provide offload instructions based on the NVMe command; and
a plurality of NVMe devices configured as a RAID array wherein each one of the NVMe devices is configured to perform offload operations based on the offload instructions based on the NVMe command and to send a command completion to the host.

18. The information handling system of claim 17, wherein the offload operations include a first XOR offloading operation and a second XOR offloading operation.

19. The information handling system of claim 18, wherein the first XOR offloading operation including: sending of a first XOR offload instruction to the NVMe device configured as a data drive; reading current data of the data drive; transferring new data write (D′) to the data drive; performing XOR operation on the read current data and the D′; and storing a result of the XOR operation to an internal buffer storage.

20. The information handling system of claim 19, wherein the internal buffer storage includes a controller memory buffer (CMB) storage.
